(19) United States
(12) Patent Application Publication
(10) Pub. No.: US 2012/0012809 A1
(43) Pub. Date: Jan. 19, 2012

(54) Switchable Junction with Intrinsic Diodes with Different Switching Threshold

(76) Inventors: Jianhua Yang, Palo Alto, CA (US); Shih-Yuan(SY) Wang, Palo Alto, CA (US); R. Stanley Williams, Portola Valley, CA (US)

(21) Appl. No.: 13/256,249

(22) PCT Filed: Jun. 25, 2009
(86) PCT No.: PCT/US09/48627

§ 371 Date: Sep. 13, 2011

(51) Int. Cl. H01L 27/26; B82Y 10/00

(52) U.S. Cl. 257/4; 977/943; 257/E27.002

(57) ABSTRACT

A switchable junction (600) having intrinsic diodes with different switching thresholds is disclosed. The switchable junction comprises a first electrode (610) formed of a first conductive material and a second electrode (630) formed of a second conductive material. The junction (600) further includes a memristive matrix (615) configured to form a first and a second electrical interface with the first and second electrodes to form a first rectifying diode interface (626) with a first switching threshold and a second rectifying diode interface (628) with a second switching threshold.

### BACKGROUND

Nanoscale electronics promise a number of advantages including significantly reduced features sizes and the potential for self-assembly and for other relatively inexpensive, non-photolithography-based fabrication methods. Nanowire crossbar arrays can be used to form a variety of electronic circuits and devices, including ultra-high density nonvolatile memory. Junction elements can be interposed between nanowires at intersections where two nanowires overlay each other. These junction elements can be programmed to maintain two or more conduction states. For example, the junction elements may have a first low resistance state and a second higher resistance state. Data can be encoded into these junction elements by selectively setting the state of the junction elements within the nanowire array. Increasing the robustness and stability of the junction elements can yield significant operational and manufacturing advantages.

### BRIEF DESCRIPTION OF THE DRAWINGS

Features and advantages of the invention will be apparent from the detailed description which follows, taken in conjunction with the accompanying drawings, which together illustrate, by way of example, features of the invention; and, wherein:

FIG. 1 is a perspective view of one illustrative embodiment of a nanowire crossbar architecture;

FIG. 2 is an isometric view of a nanowire crossbar architecture incorporating junction elements, according to one embodiment of principles described herein;

FIGS. 3A and 3B are illustrative diagrams which show current paths through a portion of a crossbar memory array, according to one embodiment of principles described herein;

FIG. 4 is a diagram of an illustrative switchable junction element having similar electrode materials, according to one embodiment of principles described herein;

FIGS. 5A and 5B are a diagram of various operational states of an illustrative switchable junction element having different types of electrode materials, according to one embodiment of principles described herein; and

FIG. 6 is a diagram of an illustrative embodiment of a switchable junction element, according to one embodiment of principles described herein.

Reference will now be made to the exemplary embodiments illustrated, and specific language will be used herein to describe the same. It will nevertheless be understood that no limitation of the scope of the invention is thereby intended.

### DETAILED DESCRIPTION

Nanoscale electronics promise a number of advantages including significantly reduced features sizes and the potential for self-assembly and for other relatively inexpensive, non-photolithography-based fabrication methods. One type of nanoscale device is a crossbar architecture. Studies of switching in nanometer-scale crossed-wire devices have previously reported that these devices could be reversibly switched and may have an “on-to-off” conductance ratio of ˜10³. These devices have been used to construct crossbar circuits and provide a route for the creation of ultra-high density nonvolatile memory. Additionally, the versatility of the crossbar architecture lends itself to the creation of other communication and logic circuitry. For example, logic families may be constructed entirely from crossbar arrays of switches or from hybrid structures composed of switches and transistors. These devices may increase the computing efficiency of CMOS circuits. These crossbar circuits may replace CMOS circuits in some circumstances and enable performance improvements of orders of magnitude without having to further shrink transistors.

The design and manufacture of nanoscale electronic devices presents a number of challenges which are being addressed to improve commercial production of nanoscale electronic devices and incorporate these devices into microscale and larger-scale systems, devices, and products.

In the following description, for purposes of explanation, numerous specific details are set forth in order to provide a thorough understanding of the present systems and methods. It will be apparent, however, to one skilled in the art that the present apparatus, systems and methods may be practiced without these specific details. Reference in the specification to “an embodiment,” “an example” or similar language means that a particular feature, structure, or characteristic described in connection with the embodiment or example is included in at least that one embodiment, but not necessarily in other embodiments. The various instances of the phrase “in one embodiment” or similar phrases in various places in the specification are not necessarily all referring to the same embodiment.

Throughout the specification, a conventional notation for the flow of electrical current is used. Specifically, the direction of a flow of positive charges (“holes”) is from the positive side of a power source to the more negative side of the power source.

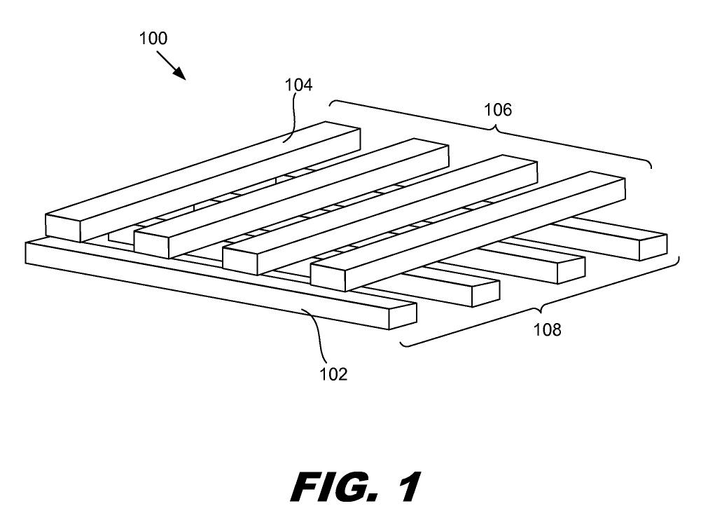

FIG. 1 is an isometric view of an illustrative nanowire crossbar array (100). The crossbar array (100) is composed of a first layer of approximately parallel nanowires (108) that are overlaid by a second layer of approximately parallel nanowires (106). The nanowires of the second layer (106) are roughly perpendicular, in orientation, to the nanowires of the first layer (108), although the orientation angle between the layers may vary. The two layers of nanowires form a lattice, or crossbar, each nanowire of the second layer (106) overlying all of the nanowires of the first layer (108) and coming into close contact with each nanowire of the first layer (108) at nanowire intersections that represent the closest contact between two nanowires.

Although individual nanowires (102, 104) in FIG. 1 are shown with rectangular cross sections, nanowires can also have square, circular, elliptical, or more complex cross sections. The nanowires may also have many different widths or diameters and aspect ratios or eccentricities. The term “nanowire crossbar” may refer to crossbars having one or more layers of submicroscale wires, microscale wires, or wires with larger dimensions, in addition to nanowires.

The layers may be fabricated using a variety of techniques including conventional photolithography as well as mechanical nanoimprinting techniques. Alternatively, nanowires can be chemically synthesized and can be deposited as layers of approximately parallel nanowires in one or more processing steps, including Langmuir-Blodgett processes. Other alternative techniques for fabricating nanowires may also be employed, such as interference lithography. Many different types of conductive and semi conductive nanowires can be chemically synthesized from metallic and semiconductor substances, from combinations of these types of substances, and from other types of substances. A nanowire crossbar may be connected to microscale address-wire leads or other electronic leads, through a variety of different methods in order to incorporate the nanowires into electrical circuits.

At nanowire intersections, nanoscale electronic components, such as resistors, and other familiar basic electronic components, can be fabricated to interconnect two overlapping nanowires. Any two nanowires connected by a switch is called a “crossbar junction.”

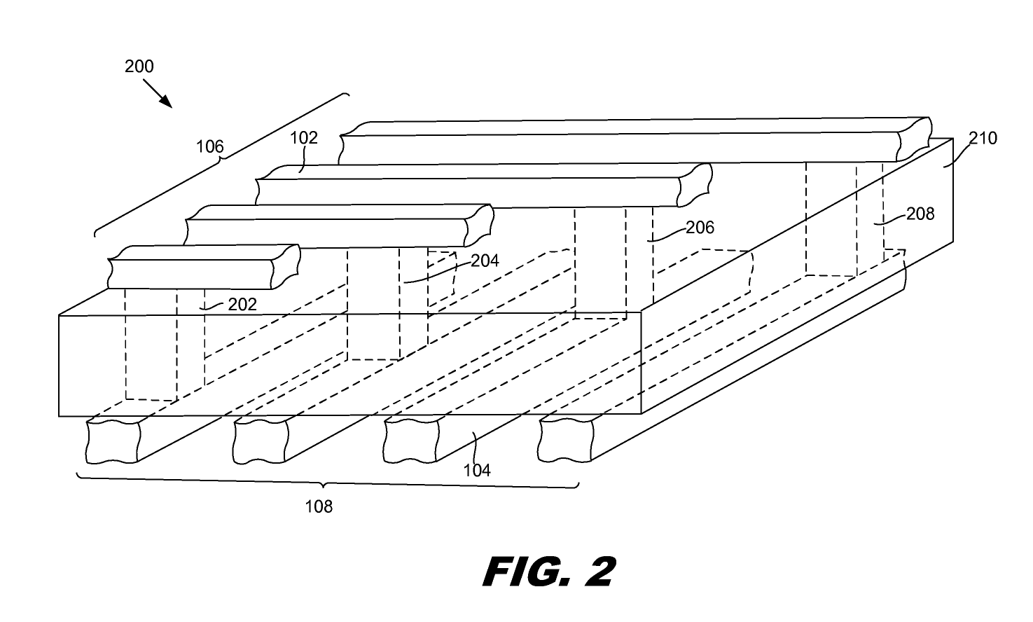

FIG. 2 shows an isometric view of an illustrative nanowire crossbar architecture (200) revealing an intermediate layer (210) disposed between a first layer of approximately parallel nanowires (108) and a second layer of approximately parallel nanowires (106). According to one illustrative embodiment, the intermediate layer (210) may be a dielectric layer. A number of junction elements (202-208) are formed in the intermediate layer at the wire intersection between wires in the top layer (106) and wires in the bottom layer (108). These junction elements (202-208) may perform a variety of functions including providing programmable switching between the nanowires. For purposes of illustration, only a few of the junction elements (202-208) are shown in FIG. 2. As discussed above, it can be desirable in many devices for a junction element to be present at each nanowire intersection. Because every wire in the first layer of nanowires (108) intersects each wire in the second layer of nanowires (106), placing a junction element at each intersection allows for any nanowire in the first layer (108) to be connected to any wire in the second layer (106).

According to one illustrative embodiment, the nanowire crossbar architecture (200) may be used to form a nonvolatile memory array. Each of the junction elements (202-208) may be used to represent one or more bits of data. For example, in the simplest case, a junction element may have two states: a conductive state and a nonconductive state. The conductive state may represent a binary “1” and the nonconductive state may represent a binary “0”, or visa versa. Binary data can be written into the crossbar architecture (200) by changing the conductive state of the junction elements. The binary data can then be retrieved by sensing the state of the junction elements (202-208). The ability to change the conductive state of the junction elements is described in further detail below.

The example above is only one illustrative embodiment of the nanowire crossbar architecture (200). A variety of other configurations could be used. For example, the crossbar architecture (200) can incorporate junction elements which have more than two states. In another example, crossbar architecture can be used to form implication logic structures and crossbar based adaptive circuits such as artificial neural networks.

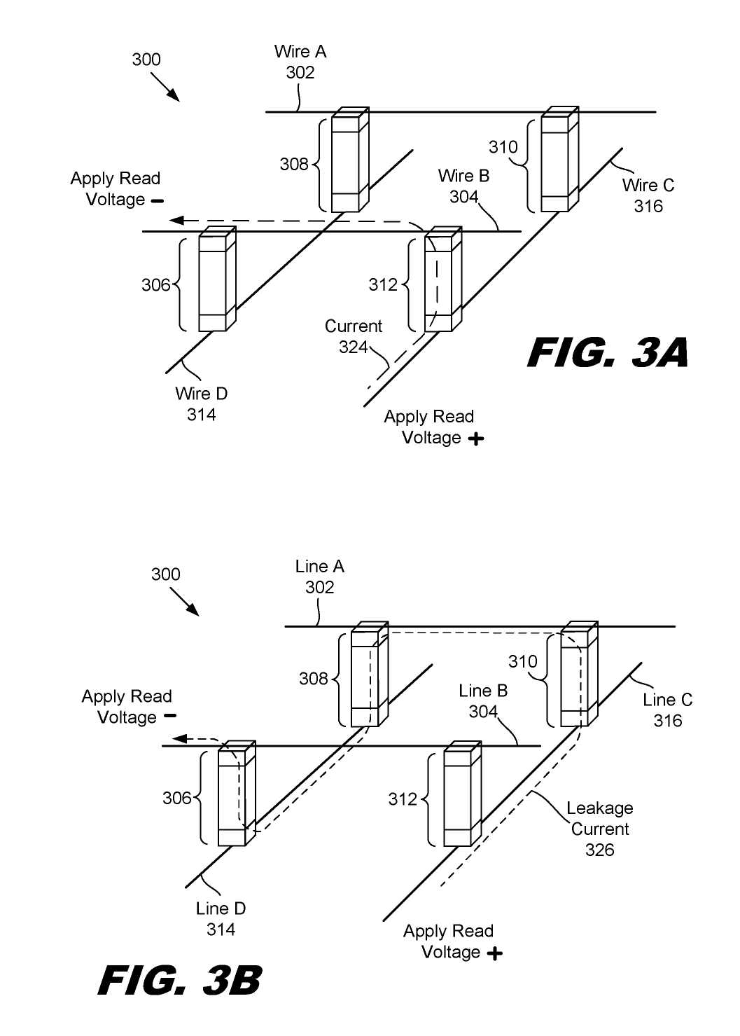

FIG. 3A is diagram which shows an illustrative crossbar architecture (300). For purposes of illustration, only a portion of the crossbar architecture (300) has been shown and the nanowires (302, 304, 314, 316) have been shown as lines. Nanowires A and B (302, 304) are in an upper layer of nanowires and nanowires C and D (314, 316) are in a lower layer and nanowires. Junctions (306-312) connect the various nanowires at their intersections.

According to one illustrative embodiment, the state of a junction (312) between wire B (304) and wire C (316) can be read by applying a negative (or ground) read voltage to wire B (304) and a positive voltage to wire C (316). Ideally, if a current (324) flows through the junction (312) when the read voltages are applied, the reading circuitry can ascertain that the junction (312) is in its conductive state. If no current, or an insubstantial current, flows through the junction (312), the reading circuitry can ascertain that the junction (312) is in its resistive state.

However, if the junctions (306-310) are purely resistive in nature (i.e. a relatively low resistance is a conductive state and a relatively high resistance is a resistive state) a number of leakage currents can also travel through other paths. These leakage currents can be thought of as “electrical noise” which obscures the desired reading of the junction (312)

FIG. 3B shows a leakage current (326) which travels through an alternative path between wire C (316) and wire B (304). In FIG. 3B, the leakage current (326) travels through three junctions (310, 308, 306) and is present on line B (304). As can be imagined, in an array of greater size than that illustrated in FIG. 3B, various leakage currents can travel through a large number of alternative paths and be present on line B (304) when it is sensed by the reading circuitry. These leakage currents can produce a significant amount of undesirable current which obscures the desired reading of the state of the junction (312).

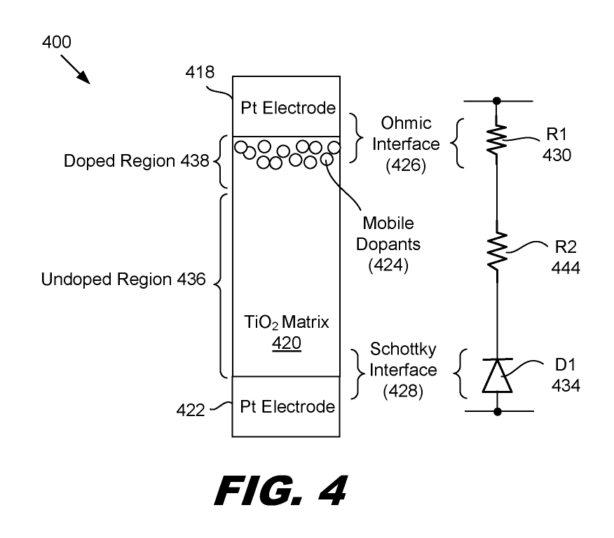

FIG. 4 illustrates a diagram which shows one embodiment of a switchable junction element (400) which can include diode-like behavior that reduces crosstalk. According to one illustrative embodiment, the junction element includes an upper platinum electrode (418) and a lower platinum electrode (422). Typically, the electrodes (418, 422) are the intersecting wires, but the electrodes may be separate elements which are electrically connected to the intersecting wires. The center portion of the junction element (400) may be made up of a memristive matrix material. A memristive matrix material is a semiconducting material that contains a number of mobile dopants. Under the influence of a relatively high programming voltage, the mobile dopants are moved through the semiconducting material, thereby changing properties of the junction. The mobile dopants remain in position when a lower reading voltage is applied, allowing the state of the junction to remain stable until another programming voltage is applied.

A number of different types of matrix/dopant combinations can be used to form a memristive matrix. Table 1, below lists a number of illustrative materials and dopants which may be used.

TABLE 1
Illustrative List of Doped Materials, Undoped Materials,
and Mobile Dopants

| Undoped | Doped | Mobile Dopant |
|---|---|---|
| TiO2 | TiO2-x | Oxygen vacancies |
| ZrO2 | ZrO2-x | Oxygen vacancies |
| HfO2 | HfO2-x | Oxygen vacancies |
| TaO | TaO₁₋ₓ | Oxygen vacancies |
| VaO | VaO₁₋ₓ | Oxygen vacancies |
| MbO | MbO₁₋ₓ | Oxygen vacancies |
| SrTiO3 | SrTiO3-x | Oxygen vacancies |
| GaN | GaN1-x | Nitrogen vacancies |
| CuCl | CuCl1-x | Chlorine vacancies |
| GaN | GaN:S | Sulfide ions |

To successfully construct a junction element with the desired rectifying behavior a number of factors can be considered, including: the band gap of the semiconductor matrix, the type and concentration of dopants in the semiconductor, the electrode metal's work function, and other factors, as can be appreciated.

According to one illustrative embodiment, the memristive matrix may be a titanium dioxide (TiO₂) matrix (420) and the mobile dopants (424) may be oxygen vacancies within the titanium dioxide matrix (420). The oxygen vacancy dopants (424) are positively charged and will be attracted to negative charges and repelled by positive charges. Consequently, by applying a negative programming voltage to the upper electrode (418) and a positive programming voltage to the bottom electrode (422), an electrical field of sufficient intensity to move the dopants (424) upward can be achieved. An electrical field of this intensity will not be present within other junctions of a nanowire array because there is only one junction where the wires connected to the upper electrode and lower electrode intersect, namely at the junction (400). As a result, each of the junctions within a nanowire array can be individually programmed to have a variable resistance, modeled as a resistor (444). The mobile dopants (424) drift upward and form a doped region (438) next to the interface between the memristive matrix (420) and the upper electrode (418). The movement of these mobile dopants from the lower regions of the matrix (420) creates a relatively lightly doped region, referred to as an undoped region (436).

Throughout the specification, drawings, and appended claims, the terms “doped region” and “undoped region” are used to indicate comparative levels of dopants or other impurities which may be present in a material. For example, the term “undoped” does not indicate the total absence of impurities or dopants, but indicates that there are significantly less impurities than in a “doped region.” The titanium dioxide matrix (420) is a semiconductor which exhibits significantly higher conductivities in doped regions and lower conductivities in undoped regions.

The high electrical conductivity of the upper electrode (418) and the relatively high electrical conductivity of the dopants (424) in the doped region (438) create a relatively good match in electrical properties at the interface. Consequently, there is a smooth electrical transition between the two materials. This electrical transition between the upper electrode (418) and the matrix (420) is called an Ohmic interface (426). The Ohmic interface (426) is characterized by relatively high electrical conductivity.

To the right of the physical diagram of the junction element (400), a corresponding electrical diagram is shown. The Ohmic interface (426) is modeled as a resistor R1 (430). As discussed above, the resistor R1 (430) will have a relatively low resistance due to the low resistance across the interface.

At the interface between the matrix (420) and the lower electrode (422), the conductive metal electrode (422) directly interfaces with the undoped region (436) of the titanium dioxide matrix. At this interface, there is a large difference in the electrical conductivity and other properties of the adjoining materials. The electrical behavior at this interface is significantly different than the Ohmic interface (426). Instead of an ohmic interface, the lower interface forms a Schottky-like interface (428). A Schottky interface (428) has a potential barrier formed at a metal-semiconductor interface which has diode-like rectifying characteristics. Schottky interfaces are different than a p-n interface in that they have a much smaller depletion width in the metal.

In one embodiment, the switchable junction element (400) may be created using multiple thin films to form the various layers. In multilayer thin films, the interface behavior may not be exactly the same as a traditional Schottky barrier. Consequently, various interfaces between the illustrative thin films are described as “Schottky-like.” The corresponding electrical element is modeled as a diode D1 (434). At moderate voltages, the diode D1 (434) allows electrical current to flow in only one direction. In the illustrative embodiment shown in FIG. 4, the diode D1 (434) only allows current to flow from the lower electrode (422) to the upper electrode (418). By incorporating this diode behavior into each of the junction elements in the crossbar array, a large portion of the cross talk currents can be blocked.

The advantages of this diode behavior can be better understood by returning to FIGS. 3A and 3B. In one embodiment, each of the junction elements (306-312) incorporates this diode behavior. Consequently, current can flow from the lower wires (314, 316) to the upper wires (302, 304) but cannot flow the opposite direction. The reading current of FIG. 3A is not impeded because the flow of the current is upward from wire C (316) to wire B (304). However, the leakage current (326) shown in FIG. 3B is blocked as the leakage current attempts to travel downward through the junction element (308) between line A (302) and line D (314). Other leakage paths within the nanowire array are similarly blocked as they attempt to pass from nanowires in the upper layer of the array to nanowires in the lower layer.

The complexity of a digital circuit, such as a digital memory, formed using a nanowire crossbar array, such as the array (100) illustrated in FIG. 1, can be significantly reduced if one side of the array can be connected to a fixed voltage level, such as ground, with the intersections being read and written to by applying a voltage to the electrode on the opposite side of the matrix. However, if the electrodes are made of the same material, a voltage applied to just one electrode, with a ground applied to the other electrode, can negate the benefits of the blocking diode.

For example, FIG. 4 shows platinum electrodes (418) and (422). If the bottom electrode (422) is connected to ground, and a voltage is applied to the top electrode (418), an electric field of the same voltage but with opposite polarity will be present to the bottom electrode (422). At voltage levels sufficient to change a position of the doped region (438), the electrical field will switch the bottom diode and thus allow current with both directions to flow through the bottom diode (434), thereby eliminating the benefit of having the blocking diode.

To overcome this limitation, the electrodes on opposite sides of the memristive matrix can be formed of different types of conductive material. As previously discussed, the interface between the memristive matrix and the electrode acts to form a Schottky-like diode interface. The switching voltage of the diode is dependent on the type of material used to form the electrode and the memristive matrix.

Illustrative conductive materials that can be used as electrodes to interface with the memristive matrix include gold, silver, aluminum, copper, platinum, palladium, ruthenium, rhodium, osmium, tungsten, molybdenum, tantalum, niobium, cobalt, nickel, iron, chromium, vanadium, titanium, iridium, iridium oxide, ruthenium oxide, titanium nitride, and titanium carbide. Various types of alloys, composites, and conductive polymers may also be used as electrodes. The material used to form the electrode is selected to form an electrode/memristive matrix interface that provides a desired range of switching voltages that enable mobile dopants within the memristive matrix to be moved sufficient to change the impedance of the interface.

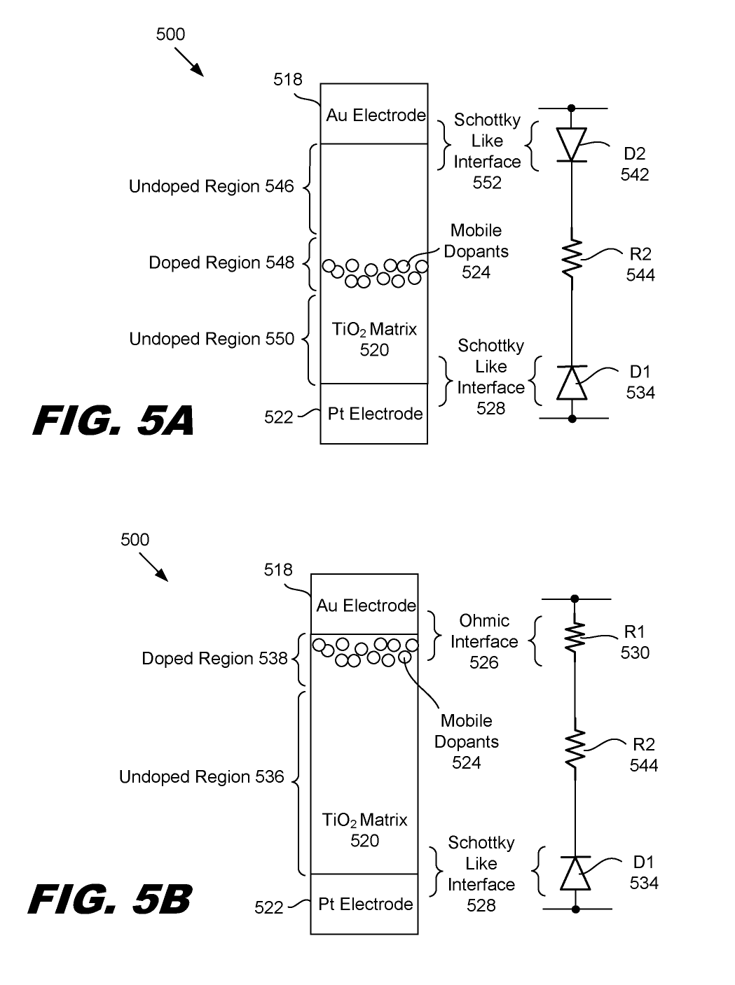

For example, FIG. 5A shows a first electrode (518) can be formed substantially from gold (Au). A second electrode (522) can be formed substantially from platinum (Pt). In the example in FIG. 5A, a junction between the gold electrode 518 and the titanium dioxide memristive matrix (520), can create a first Schottky-like diode interface (552) with a switching voltage of approximately 0.5 volts. This is characterized in the electrical model of the junction, shown to the right of the cross-sectional diagram, as a diode D2 (542). The Schottky-like diode interface (528) created by the platinum electrode (522) interface with the titanium dioxide memristive matrix (520) forms a Schottky-like diode (534) with a switching voltage of approximately 1.5 volts. This difference in switching voltage allows one of the diodes to be switched on, while leaving the other diode switched off. This enables the platinum bottom electrode to be connected to a constant voltage, such as ground. A single variable voltage can then be applied to the top electrode to switch the state of the switchable junction element. The ability to connect one layer of the junction to ground enables a significant reduction in complexity to read and write to the junction with the single voltage source connected to the junction having the lower switching voltage.

As previously discussed, the doped region (548) of the matrix includes a plurality of mobile dopants. The type of dopants used depends on the material from which the memristive matrix is formed. In the example, when titanium dioxide (TiO₂) is used to form the memristive matrix, the doped region (548) is comprised of oxygen vacancies. When a positive voltage between 0.5 V and 1.5 V is applied to the gold electrode (518), it creates an electric field that drives the doped region away from the gold electrode (518). Since the applied voltage is less than the switching voltage of the platinum electrode (522) interface, the diode (534) comprising the Schottky-like interface (528) remains in the off position and creates a barrier to current flow, thereby significantly reducing leakage current and crosstalk. When the doped region (548) is a selected distance away from the gold electrode, the conductivity of the switchable junction element (500) changes to form a head-to-head rectifier circuit, as shown in FIG. 5A. The combined resistance of the undoped region (546), the doped region (548), and the undoped region (550) in the memristive matrix is modeled as a resistor (544) in the electrical model of the junction in FIG. 5A.

The location of the doped region (548) in FIG. 5A represents an “OFF” state of the switchable junction element (500). In the off state, the resistance may be on the order of 10⁵ ohms to 10⁷ ohms, depending on the type of materials used. The switchable junction element's state can be read by applying a read voltage that is less than the lowest switching voltage of the electrode interfaces (552, 528). In this example, the reading voltage can be less than +/−0.5 volts, with the read voltage typically around 0.2 volts.

The switchable junction element (500) can be switched to the “ON” state, as shown in FIG. 5B, by applying a negative voltage greater than 0.5 volts to the gold electrode 518. A voltage of less than negative 1.5 volts will ensure that the platinum electrode (522) interface (528) does not switch, significantly reducing leakage current and crosstalk that occur during a write cycle. When the doped region (538) migrates near the gold electrode (518), it forms an ohmic interface (526), as previously discussed. The relatively low resistance of the ohmic interface is modeled by resistor (530). The resistance of the junction (500) in the “ON” state is on the order of 10² to 10⁴, or about 10³ times less than the resistance in the “OFF” state. This large change in resistance can be sensed by applying the reading voltage, as discussed above.

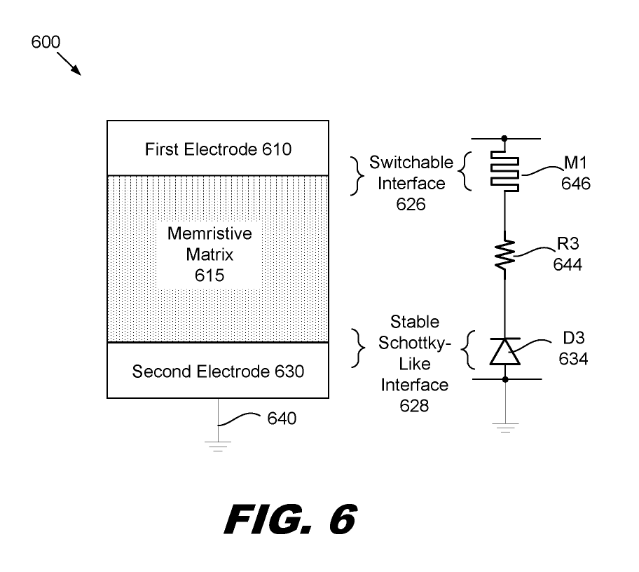

A more generic illustration of the example in FIGS. 5A and 5B is provided in FIG. 6. FIG. 6 shows a first electrode (610) electrically coupled to a memristive matrix (615), which is electrically coupled to a second electrode 630. The first electrode is selected to form a first rectifying diode interface having a diode switching voltage V₁ that is less than the diode switching voltage V₂ of the second rectifying diode interface formed between the second electrode (630) and the memristive matrix (615). The second electrode may be connected to ground (640), or another selected constant voltage. The interface between the first electrode and the memristive matrix forms a switchable interface (626), modeled as a memristor (646).

The interface between the second electrode (630) and the memristive matrix (615) forms a stable Schottky-like diode interface (628), modeled as a diode 634. The memristive matrix is modeled as a resistor (644). A variable voltage source V₁<V<V₂ can be applied to the top electrode (610) to write to the switchable junction element (600). The polarity of V is determined based on the charge of the mobile dopants. A polarity is selected to create an electric field within the memristive matrix that drives the dopants towards the first electrode (610) to form an “ON” state of the switchable junction element (600). An opposite polarity is selected to move the switchable junction element (600) to the “OFF” state. Intuitively, the state selected as “on” and “off” can be chosen arbitrarily, or based upon the needs of a larger system.

The state of the switchable junction element (600) can be read by applying a voltage that is less than V₁. The Schottky-like diode interface (628) significantly limits leakage current and crosstalk during both read and write cycles. Depending on the requirements of the specific application, the first electrode can be constructed from a material selected to form a stable Schottky-like diode interface and the material of the second electrode can accordingly be selected to form a switching interface.

The type of conductive material used to form the electrode can be selected based on the desired switching voltage of the junction. The switching voltage is dependent upon the physical properties of the electrode/memristive matrix interface. Two different switching voltages are desired for the two electrodes coupled to the memristive matrix. Typically a relatively low switching voltage is desired to reduce the amount of power consumed in switching. As previously discussed, the diode switching voltage for an Au/TiO₂ interface is approximately 0.5 volts. The diode switching voltage for a Pt/TiO₂ interface is about 1.5 volts.

The difference between the switching voltages of the Schottky-like diode interface enables one electrode e.g., (628) to be grounded or set at a fixed voltage. A voltage between the lower diode switching voltage and the greater diode switching voltage (0.5<V<1.5 when using gold and platinum) can be applied to the electrode with the lower diode switching voltage to enable the switchable junction element (600) to be switched between a relatively high impedance and a relatively low impedance. By staying within this voltage range, the junction can be switched while maintaining the Schottky-like diode (634) at the interface (628) of the memristive matrix (615) with the electrode (630) having the greater diode switching voltage. This enables the junction (600) to be switched while maintaining a barrier to current flow, thereby significantly reducing leakage current and crosstalk.

The ability to apply a ground or fixed voltage to one electrode of the switchable junction element and switch the junction using a single, variable voltage, significantly reduces the complexity of reading and writing to a nanowire crossbar array, as illustrated in FIG. 1. Rather than having to apply two different voltages to the two electrodes of each switchable junction in the array, the ability to apply a single voltage to read or write to each junction can substantially reduce the complexity and cost of a device constructed using a crossbar array.

While the forgoing examples are illustrative of the principles of the present invention in one or more particular applications, it will be apparent to those of ordinary skill in the art that numerous modifications in form, usage and details of implementation can be made without the exercise of inventive faculty, and without departing from the principles and concepts of the invention. Accordingly, it is not intended that the invention be limited, except as by the claims set forth below.

What is claimed is:

1. A switchable junction (500) having intrinsic diodes (534, 542) with different switching thresholds, comprising:
a first electrode (518) formed of a first conductive material:
a second electrode (522) formed of a second conductive material;
a memristive matrix (520) configured to form a first and a second electrical interface with the first (518) and second (522) electrodes to form a first rectifying diode interface (552) with a first switching threshold and a second rectifying diode interface (528) with a second switching threshold.

2. The switchable junction according to claim 1, wherein the first conductive material and the second conductive material are formed from a material selected from the group consisting of gold, silver, aluminum, copper, platinum, palladium, ruthenium, rhodium, osmium, tungsten, molybdenum, tantalum, niobium, cobalt, nickel, iron, chromium, vanadium, titanium, iridium, iridium oxide, ruthenium oxide, titanium nitride, and titanium carbide.

3. The switchable junction of any of the above claims, wherein the memristive matrix (520) is formed from a material selected from the group consisting of titanium dioxide, zirconium dioxide, hafnium dioxide, tantalum oxide, vanadium oxide, molybdenum oxide, strontium titanium trioxide, gallium nitride, and copper chloride.

4. The switchable junction of any of the above claims, wherein the memristive matrix material includes mobile dopants selected from the group consisting of oxygen vacancies, nitrogen vacancies, chlorine vacancies, and sulfide ions.

5. The switchable junction of any of the above claims, wherein the first switching threshold is less than the second switching threshold to enable a voltage to be applied between the first (518) and second (522) electrodes to switch the first rectifying diode interface (552) without switching the second rectifying diode interface (528).

6. The switchable junction of any of the above claims, wherein the first switching threshold is greater than the second switching threshold to enable a voltage to be applied between the first (518) and second (522) electrodes to switch the second rectifying diode interface (522) without switching the first rectifying diode interface (528).

7. The switchable junction of any of the above claims, further comprising a plurality of the switchable junctions aligned to form a cross bar array (100).

8. The switchable junction according to any of the above claims, in which the switchable junction (500) is configured to form a switchable electrical connection between two nanowires (102, 104) in a crossbar array (200).

9. The switchable junction according to any of the above claims, wherein the mobile dopants (424) which are configured to be moved through the memristive matrix (615) by an application of a programming voltage across the first (610) and second (630) electrodes; a mobile dopant distribution being configured to define a programmable conductance of the electrical interface (626).

10. The switchable junction according to any of the above claims, wherein one of the first (518) and second (522) electrodes are connected to ground (640), with one of a switching voltage and a reading voltage applied to the other of the first (518) and second (522) electrodes.

11. A switchable junction (500) having at least two intrinsic diodes with different switching thresholds, comprising:
a first electrode (518) formed of a first conductive material:
a second electrode (522) formed of a second conductive material;
a memristive matrix (520) having mobile dopants (524);
a first electrical interface (552) between the memristive matrix and the first electrode (518) operable to form a first rectifying diode interface (542) with a first switching threshold;
a second electrical interface (528) between the memristive matrix and the second electrode (522) operable to form a second rectifying diode interface (534) with a second switching threshold that is greater than the first switching threshold;
wherein the second electrode (522) is operable to be connected to a fixed voltage, with a selected voltage applied between the first electrode (518) and the second electrode (522) to distribute the mobile dopants (524) to a desired location with respect to the first electrical interface (552) to enable a resistance of the first electrical interface (552) to be switched based on the location of the mobile dopants while maintaining the second rectifying diode interface (534) to block a reverse current.

12. The switchable junction according to claim 11, wherein the fixed voltage is a ground.

13. The switchable junction according to claim 11, wherein the selected voltage has a level greater than the first switching voltage and less than the second switching voltage.

14. The switchable junction according to claims 11, 12, and 13, in which the switchable junction (500) is configured to form a switchable electrical connection between two nanowires (102, 104) in a crossbar array (200).

15. The switchable junction according to claims 11, 12, and 13, and 14 wherein the mobile dopants (424) which are configured to be moved through the memristive matrix (615) by the application of a programming voltage across the first (610) and second (630) electrodes; the mobile dopant distribution being configured to define the programmable conductance of the electrical interface (626).
